(19) United States
(12) Patent Application Publication
(10) Pub. No.: US 2025/0243584 A1
(43) Pub. Date: Jul. 31, 2025

(54) SUSCEPTOR WITH A TEXTURED SURFACE

(71) Applicant: Applied Materials, Inc., Santa Clara, CA (US)

(72) Inventors: Wei-Sheng LEI, San Jose, CA (US); Christian GRONET, Santa Clara, CA (US); Anantha K. SUBRAMANI, San Jose, CA (US)

(21) Appl. No.: 18/424,156

(22) Filed: Jan. 26, 2024

(51) Int. Cl. C23C 16/458; B23K 26/0622; B23K 26/386; B23K 26/402; C23C 16/46; C30B 25/10; C30B 25/12

(52) U.S. Cl. CPC C23C 16/4583; B23K 26/0624; B23K 26/386; B23K 26/402; C23C 16/46; C30B 25/10; C30B 25/12

(57) ABSTRACT

Disclosed herewith are a susceptor, a processing chamber having the susceptor, and a method for making the susceptor. The susceptor includes a body, an upper surface area supported by the body, and a lower surface area support by the body. The upper surface area and the lower surface area comprise an array of blind holes, the blind holes having a diameter of at least 5 um, a depth of at least 5 um, and an aspect ratio of at least 1:1. The method includes forming the array of the blind holes in the upper surface area and the lower surface area of the susceptor and forming surface textures on the surfaces of the susceptor.

### BACKGROUND

### Field

The present disclosure relates to a susceptor with a treated surface, and more specifically relates to a susceptor with a textured surface for emissivity improvement.

### Description of the Related Art

When a silicon or silicon carbide (SiC) substrate is processed in a processing chamber, a susceptor is used to carry a substrate. The susceptor is often made of a material of a high purity, chemical resistance, thermal stability, and/or strength, such as graphite and silicon carbide. A susceptor made of graphite or silicon carbide typically has an emissivity value of about 0.8 for the infrared light having a wavelength between 1 and 5 um. It is noted that emissivity has a value range, which can vary between 1 for a black body (no emission or reflectivity) to 0 for a perfect reflector, also known as an inverse measure of reflectivity.

During the processing of a substrate, heating lamps are used to heat the substrate. The heating lamps and adjacent parts can reach very high temperature and may emit light in the wavelength range between 1 and 5 um. When the susceptor has an emissivity value of 0.8, a noticeable portion of the light emitted by the heating lamps and adjacent parts may be reflected off the susceptor, which can interfere the temperature measurement of a thermal sensor, such as a pyrometer.

Thus, a need exists for an improved design of a susceptor with a higher emissivity.

### SUMMARY

Disclosed herein are Disclosed herewith are a susceptor, a processing chamber having the susceptor, and a method for making the susceptor. The susceptor for supporting a substrate inside a processing chamber, the susceptor includes a body having an upper surface area and a lower surface area. A first plurality of blind holes are formed in the upper surface area of the body; and a second plurality of blind holes are formed in the lower surface area of the body. At least one blind hole from the first and second plurality of blind holes has a diameter of at least 5 um, a depth of at least 5 um, and an aspect ratio of at least 1:1. The susceptor also includes a surface texture formed in the upper surface area. The plurality of blind holes may be closely pitched or overlap with each other, generating one or more scribed lines. The scribed lines may have a ratio of width to depth no greater than 1:1.

In an example, the method of making a susceptor includes forming a first plurality of blind holes in a lower surface area of the susceptor; forming a second plurality of blind holes in an upper surface area of the susceptor; and forming a surface texture on the upper surface area and the lower surface area of the susceptor. At least one blind hole of the second plurality of the blind holes has a diameter of at least 5 um, a depth of at least 5 um, and an aspect ratio of at least 1:1.

In another example, the processing chamber includes the susceptor as set forth in the present disclosure and a heating lamp operable to heat the susceptor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic top view of a processing system, according to an embodiment of the present disclosure.

FIG. 2 illustrates a schematic cross-sectional view of an EPI processing chamber, according to an embodiment of the present disclosure.

FIG. 3 illustrates a schematic diagram of a processing tool for making a surface treatment to a susceptor, according to an embodiment of the present disclosure.

FIG. 4 illustrates a flow pattern of treating surfaces of a susceptor, according to an embodiment of the present disclosure.

FIG. 5 illustrates a schematic cross-sectional view of a susceptor having blind holes and textured surfaces, according to an embodiment of the present disclosure.

FIG. 6a illustrates a packing pattern of blind holes in a susceptor, according to an embodiment of the present disclosure.

FIG. 6b illustrates a denser packing pattern of blind holes in a susceptor, according to an embodiment of the present disclosure.

FIG. 7a illustrates bind holes in a susceptor, according to an embodiment of the present disclosure.

FIG. 7b illustrates a textured surface of a susceptor, according to an embodiment of the present disclosure.

FIG. 8 illustrates an image of a susceptor made of silicon carbide, according to an embodiment of the present disclosure.

FIG. 9 illustrates a method for making a susceptor, according to an embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

In a processing chamber, a pyrometer may be used to measure temperature of a substrate by detecting certain wavelength of infrared light emitted by the substrate. This temperature measurement may be interfered by light that is emitted by other parts of the processing chamber and reflected off the surface of a susceptor. Thus, it is desirable to increase the emissivity of the susceptor such that very little light may be reflected off by the susceptor.

The susceptor as set forth in the present disclosure are made of a material of a high emissivity, such as graphite, silicon carbide (SiC), or tantalum carbide (TaC). The susceptor may be coated with one or more protective layers, such as SiC, and TaC. In addition, the susceptor are treated by beams of radiation, such as pulsed laser beams. The radiation beams have a high energy intensity such that blind holes are formed on the surface areas of the susceptor. The blind holes is configured to trap light emitted by the heating lamps. For example, the blind holes may have a predetermined hole-to-hole pitch, aspect ratio, diameter, and/or depth selected based on the wavelength of the light used for the temperature measurement and throughput of a fabrication process. The term an “aspect ratio” with regard to a blind hole as used in the present disclosure may be understood as a ratio of the hole depth to the hole diameter.

Once the blind holes are formed, the surfaces of the susceptor may be textured, such as treated by another radiation beams with lower energy densities. The radiation beams with lower energy densities can roughen the surfaces with the creation of nano/micro-structures on the surfaces. The nano/micro-structures can further reduce the reflectivity of the surfaces. With the blind holes and the surface textures, a susceptor made according to an embodiment of the present disclosure can have an emissivity of at least 0.95.

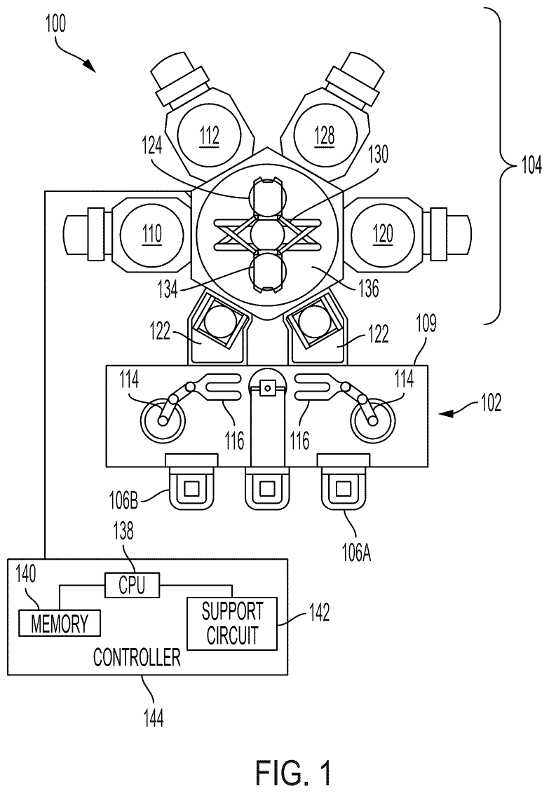

FIG. 1 illustrates a schematic top view of a processing system 100, according to one or more embodiments. The processing system 100 includes one or more load lock chambers 122 (two are shown in FIG. 1), a processing platform 104, a factory interface 102, and a controller 144. In one or more embodiments, the processing system 100 is based on a CENTURA® integrated processing system, from Applied Materials, Inc., located in Santa Clara, California. It is contemplated that other processing systems (including those from other manufacturers) may be adapted to benefit from the disclosure. In one or more embodiments, the processing system includes a susceptor with a treated surface as set forth in the present disclosure to support a substrate.

The platform 104 includes a plurality of processing chambers 110, 112, 120, 128, and the one or more load lock chambers 122 that are coupled to a transfer chamber 136. The plurality of processing chambers 110, 112, 120, 128 may include an EPI chamber, a rapid thermal process chamber, an etch chamber, and any other suitable chambers. The transfer chamber 136 can be maintained under vacuum, or can be maintained at an ambient (e.g., atmospheric) pressure. Two load lock chambers 122 are shown in FIG. 1. The factory interface 102 is coupled to the transfer chamber 136 through the load lock chambers 122.

In one or more embodiments, the factory interface 102 includes at least one docking station 109 and at least one factory interface robot 114 to facilitate the transfer of substrates. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, 128.

The controller 144 is coupled to the processing system 100 and is used to control processes and methods, such as the operations of the methods described herein (for example the operations of the method 1000 and/or the method 1050 described below). The controller 144 includes a central processing unit (CPU) 138, a memory 140 containing instructions, and support circuits 142 for the CPU. The controller 144 controls various items directly, or via other computers and/or controllers.

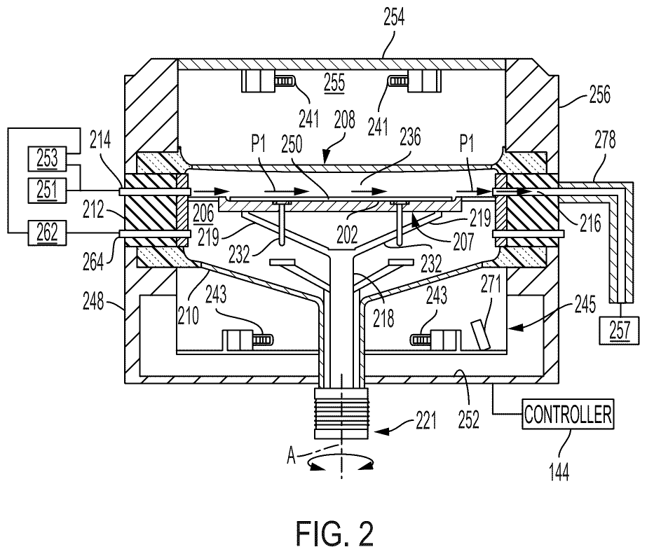

FIG. 2 illustrates a schematic cross-sectional view of an EPI processing chamber 200 according to an embodiment. The EPI processing chamber 200 is a deposition chamber to grow an EPI layer on a substrate 202. The processing chamber 200 can be used as one or more of the processing chambers 110, 112, 128 shown in FIG. 1.

The processing chamber 200 includes an upper body 256, a lower body 248 disposed below the upper body 256, and a flow module 212 disposed between the upper body 256 and the lower body 248. The upper body 256, the flow module 212, and the lower body 248 form a chamber body. Disposed within the chamber body is a susceptor 206, an upper window 208 (such as an upper dome), a lower window 210 (such as a lower dome), a plurality of upper heat sources 241, and a plurality of lower heat sources 243. As shown, the controller 144 is in communication with the processing chamber 200 and is used to control processes and methods of at least the processing chamber 200.

According to an embodiment, the heat sources 241, 243 are lamps that are capable of generating infrared radiation. Other heat sources that are capable of generating infrared radiation are contemplated, such as resistive heaters, light emitting diodes (LEDs), and/or lasers.

The susceptor 206 is disposed between the upper window 208 and the lower window 210. The susceptor 206 supports the substrate 202 and has a plurality of through holes 207. The plurality of upper heat sources 241 are disposed between the upper window 208 and a lid 254. The plurality of upper heat sources 241 form a portion of the upper heating module 255.

According to an embodiment, the susceptor 206 is made of a high emissivity material, such as graphite or silicon carbide. The susceptor 206 includes a treated surface area to further improve emissivity. The treated surface area includes densely packed blind holes. The treated surface area may also include surface textures, such as a layer of micro-structures. The blind holes and the surface textures may be created by pulsed lasers or any other suitable methods.

The processing chamber 200 includes one or more thermal sensors 271 configured to detect a thermal condition of the processing chamber 200. In one or more embodiments, the one or more thermal sensors 271 may include one or more cameras, one or more pyrometers, one or more thermoelectric sensors, and/or one or more thermal labels. The one or more thermal sensors 271 can be mounted, for example, below the lower window 210 (as shown in FIG. 2), or above the upper window 208 (such as on or in the lid 254), or any other suitable place in the processing chamber 200. In one example, a pyrometer is mounted above the upper window 208 and is configured to remotely measure temperature of the substrate 202 and the susceptor 206 during the growth process of an EPI layer.

The plurality of lower heat sources 243 are disposed between the lower window 210 and a chamber floor 252. The plurality of lower heat sources 243 form a portion of a lower heating module 245. The upper window 208 is an upper dome and is formed at least partially of an energy transmissive material, such as quartz. The lower window 210 is a lower dome and is formed at least partially of an energy transmissive material, such as quartz.

The susceptor 206 is supported by an inner shaft 218 coupled with a motion assembly 221. The motion assembly 221 includes one or more actuators and/or adjustment devices that provide movement and/or adjustment for the inner shaft 218, which, in turn, moves the susceptor 206 and the substrate 202. The susceptor 206 is coupled to the inner shaft 218 through one or more arms 219. The lift pin holes 207 of the susceptor 206 are each sized to accommodate a lift pin 232 that is used to lift the substrate 202 from the susceptor 206 or lower the same to the susceptor 206.

The flow module 212 includes a plurality of gas inlets 214, a plurality of purge gas inlets 264, and one or more gas exhaust outlets 216. The gas inlets 214 are connected with a plurality of process gas sources 251, 253 and provides a cross-flow of precursors across a top surface 250 of the substrate 202. The purge gas inlets 264 are connected to a purge gas source 262 and provide purge gas to the EPI chamber 200. The plurality of gas inlets 214 and the plurality of purge gas inlets 264 are disposed on the opposite side of the flow module 212 from the one or more gas exhaust outlets 216. The one or more gas exhaust outlets 216 are connected to or include an exhaust system 278. The exhaust system 278 fluidly connects the one or more gas exhaust outlets 216 and the exhaust pump 257. The exhaust system 278 is disposed on an opposite side of the processing chamber 200 relative to the flow module 212.

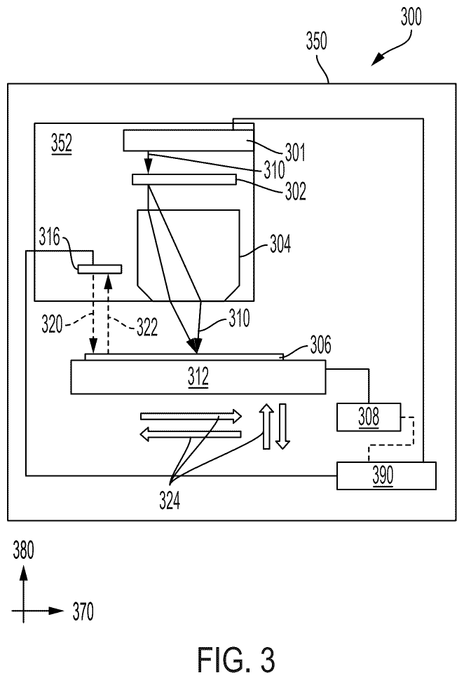

FIG. 3 illustrates a schematic configuration of a processing tool 300 for treating the surface areas of a susceptor, according to an embodiment of the present disclosure. The processing tool 300 is configured to direct radiation beams, such as pulsed laser beams, to the surface of the susceptor 306. The processing tool 300 is not limited to use laser energy for treating a surface area and may include any suitable energy, such as thermal energy, light energy, or other suitable energy, to treat the surface area of the susceptor 306.

The processing tool 300 has an enclosure 350 housing a laser module 352, a translation stage 312 configured to carry an object 306 for treatment and configured to move the object 306 in a plurality of directions 324, including both horizontal and vertical directions. An actuator system 308 may also be coupled to the translation stage 312 to assist the control and movement of the translation stage 312.

The laser module 352 includes a laser radiation source 301, at least one scanner 302 and an optical focusing module 304 disposed above the translation stage 312. In one example, the laser radiation source 301 may be a light source made from diode pumped Nd:YAG, Nd:YVO4 crystalline rod, innoslab, disk, or fiber and other light source that can provide and emit a pulsed or continuous wave of radiation.

The scanner 302 is configured to scan an energy beam across a scanning field of a limited range. In one example, the scanner 302 directs the energy beam to cover a processing cell corresponding to the scanning field on the surface of the object 306, such as a square area of 20×20 mm or any other size. The scanner 302 may be a digital micro-mirror device, a galvanometer, a polygon scanner, an oscillator, or any other suitable scanners.

The focusing optical module 304 transforms the radiation 310 emitted by the laser radiation source 301 into a spot or other suitable beam configuration. In an embodiment, the radiation 310 is selectively applied to the surface of a susceptor according to a packing pattern.

A detector 316 is disposed in the laser module 352 to inspect the object 306. In one example, the detector 316 may include a light source 320. In one example, the detector 316 and light source 320 may form part of an optical microscope (OM) used to observe texture and/or packing patterns or features formed on the object 306. In yet another example, the detector 316 may include a camera that may capture images.

In one example, the translation stage 312 is configured to move in both X-direction 370 and Y-direction 380 relative to the laser module 152 and/or the susceptor 306. In another example, thus causing the beam of energy to move relative to the object 306 that is disposed on the translation stage 312. The translation stage 312 may use any suitable translation mechanism, such as a conveyor system, rack and pinion system, or an x/y actuator, a multiple robot, or other suitable mechanical or electro-mechanical mechanism.

The translation stage 312 and the scanner 302 are configured to allow the radiation 310 to cover the entire surface of the object 306. The controller 390 may be a high speed computer configured to control operations of the laser module 352, the translation stage 312, and the actuator system 308 to perform the surface treatment as set forth in the present disclosure.

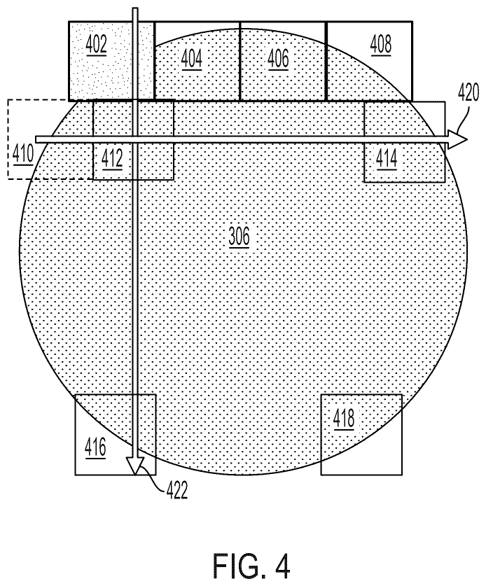

FIG. 4 illustrates a flow pattern of treating surfaces of the susceptor 306, according to an embodiment of the present disclosure. As the scanning field of the scanner 302 has a limited range, the surface of the susceptor 306 is divided into a grid of processing cells 402-408 and 410-418. Each processing cell may not be greater than the scanning field of the scanner 302. In an embodiment, the processing cells are scanned sequentially. For example, the scanner 302 is configured to scan the first processing cell 402. Then, the translation stage 312 moves the susceptor 306 along an X direction 420 or a Y direction 422 to bring the next processing cell 404 into the scanning field of the scanner 302. The iterations between the scanning by the scanner 302 and the movement of the translation state 312 repeat until all the processing cells are scanned by the scanner 302. In another embodiment, additional scanners 302 and radiation 310 may be included in the processing tool such that a plurality of processing cells may be scanned in parallel. In another embodiment, a scanner has a large scan field that can cover the entire susceptor surface area and no translation stage is needed.

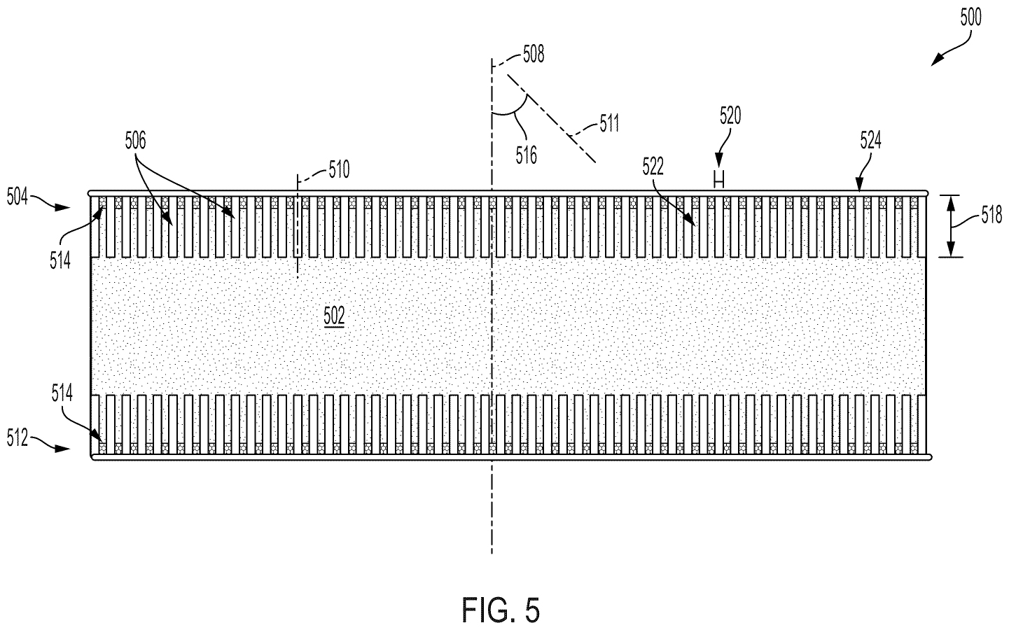

FIG. 5 illustrates a schematic cross-sectional view of a susceptor 500 having a treated surface, according to an embodiment of the present disclosure. The susceptor 500 includes a body 502. The body 502 has an upper treated surface area 504 and a lower treated surface area 512 formed on opposite sides of the body 502. The susceptor 500 may be made of any material of a high emissivity. In one example, the susceptor 500 is made of graphite, silicon carbide, tantalum carbide, or any other suitable materials.

Optionally, the upper and lower surface areas 504 and 512 may include one or more layers of a protective material 514, such as silicon carbide, TaC, or other suitable protective materials. In an embodiment, the layer of the protective material 514 has a higher emissivity than the body 502. The body 502 may have a thickness in the range of 0.5 to 6 mm, 1.5 to 3 mm, or about 3 mm.

In an embodiment, the upper and lower surface areas 504 and 512 include a plurality of blind holes 506 configured to trap light used for the temperature measurement. The light may have a wavelength in the range between 1 um to 5 um. The bind holes 506 may have an orientation (e.g., center axis) 510 that is substantially parallel to an axis 508 of the susceptor 500. In another example, the orientation 510 of the blind holes 506 may be slanted and may form an angle 516 with the axis 508. The angle 516 may be less than 30 degrees, less than 20 degrees, less than 10 degrees, or less than 5 degrees.

The blind holes 506 may have a predetermined dimension selected based on the wavelength of the light to be trapped and throughput of a surface treatment process. For example, when the blind holes 506 are configured to trap light of a wavelength between 1 to 5 um, the depth 518 of the blind holes 506 may be at least 5 um or between 5 and 50 um. The diameter 520 of the blind holes 506 may not be less than 5 um. In another embodiment, an aspect ratio of the blind holes 506 may not be less than 1:1. For example, the diameter-to-depth ratio of the blind holes 506 may be between 1:1 to 1:10, 1:2 to 1:5, or 1:3 to 1:4. The blind holes 506 may be open (e.g., exposed) through an opening in the layer of the protective material 514.

The upper and lower surface areas 504 and 512 also include walls 522 separating adjacent blind holes 506. The thickness of the walls 522 is defined as the shortest distance between the two separated blind holes 506. The thickness of the walls 522 is configured to maintain the mechanical integrity of the susceptor 500. In an embodiment, the thickness of the walls 522 may be between 1 to 15 um or between 2 to 6 um. In an embodiment, the surfaces of the walls 522 are roughened with a layer of nano/micro-structures to reduce emissivity.

In an embodiment, the upper and lower surface areas 504 and 512 include surface textures 524 to reduce the reflectivity of impinging light. Any reflected light by the surfaces of the walls 522 would lower the emissivity of the susceptor 500. Thus, the surfaces of the walls 522 and the blind holes are configured to have a roughened surface texture 524 to reduce reflectivity. The roughened surface texture 524 may include a plurality of nano/micro-structures created by the radiation 310. In an embodiment, the surface texture 524 and the blind holes 506 are created by separate processes of the processing tool 300. The surface texture 524 may be formed by less powerful lasers than that used to form the blind holes 506. For example, the power of the lasers used to form the surface texture 524 may be about 20%, 10%, 5%, or even a lesser amount of that to form the blind holes 506. The spot diameter of the lasers used to form the surface texture 524 may be greater than that to form the blind holes 506. For example, the spot diameter of the lasers used to form the surface texture 524 may be two, three, or even greater times of that to form the blind holes 506.

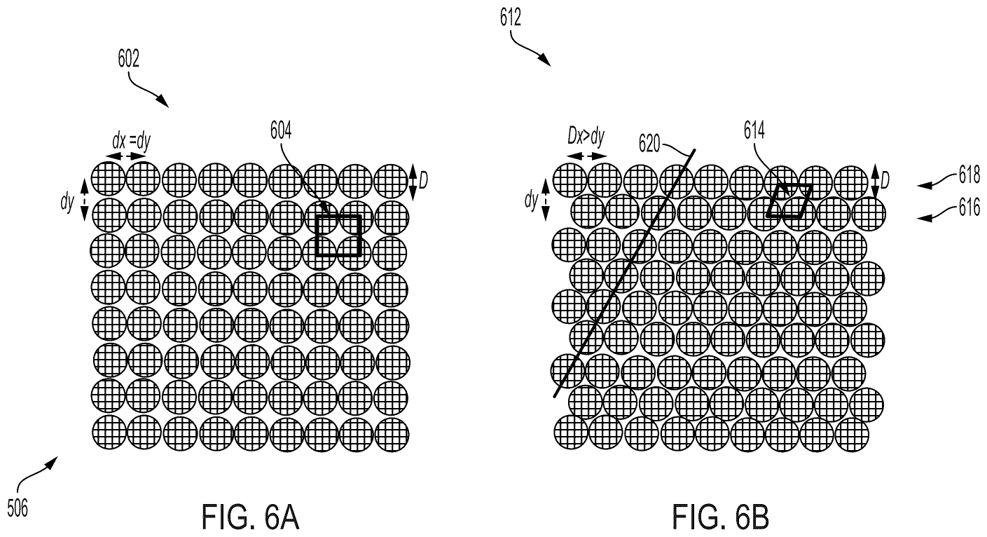

FIG. 6a illustrates a schematic packing pattern 602 of the blind holes 506, according to an embodiment of the present disclosure. In this packing pattern 602, all the blind holes 506 have a same diameter D. The blind holes 506 include 72 blind holes arranged in an 8×9 2D array, where the column and row are arranged orthogonally. As a result, any adjacent four (4) blind holes form a square 604. The hole-to-hole pitch (center to center distance) dx between two consecutive blind holes in a row is the same as the hole-to-hole pitch (center to center distance) dy between two consecutive blind holes in a column.

FIG. 6b illustrates a schematic denser packing pattern 612 of the blind holes 506, according to an embodiment of the present disclosure. In this packing pattern 612, the blind holes 506 of FIG. 6b have the same diameter D as those in FIG. 6a. But, the blind holes 506 in FIG. 6b are arranged in a manner that adjacent rows are offset from each other. For example, each of rows 616 and 618 has nine (9) blind holes, but each blind hole in the row 618 is placed between every two blind holes of 618. As a result, any adjacent four (4) blind holes in the packing patter 612 form a parallelogram 614. The hole-to hole pitch (center to center distance) dy between two consecutive blind holes in a column direction is now reduced. This packing patters 612 forms a denser arrangement of blind holes than that of the packing pattern 602. For example, in a similar-sized area, the packing pattern 612 can pack approximately 81 (9×9 array) blind holes which are 9 more blind holes that that of the packing pattern 602. In an embodiment, the row pitch dx or the row pitch dy may be smaller than the hole diameter D. As a result, the blind holes are very densely packed and overlap with each other. The overlapped bind holes can form one or more scribed lines 620 in the packing pattern 612.

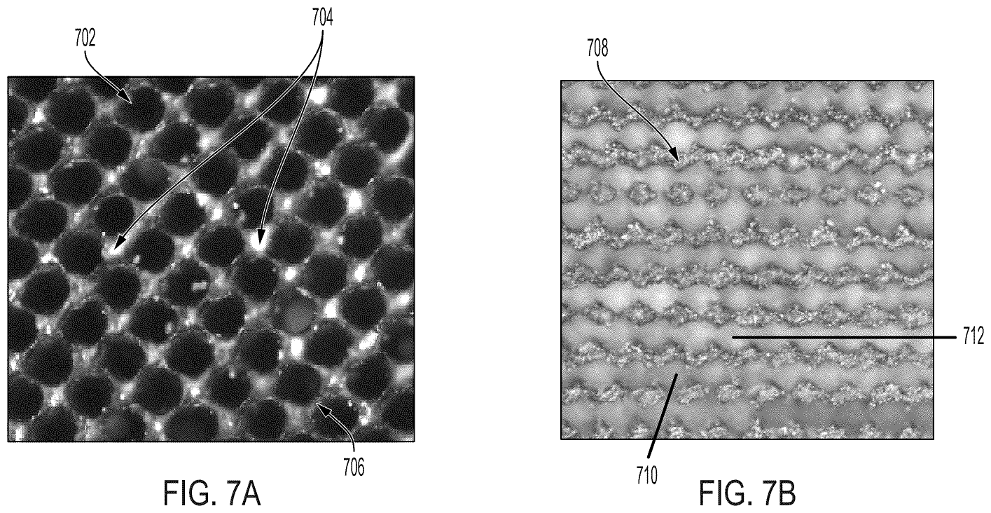

FIG. 7a illustrates blind holes formed in a susceptor, according to an embodiment of the present disclosure. The blind holes 702 are formed in a graphite susceptor according to the 612 packing pattern. The diameter of the blind holes 702 is about 35 um. The walls 706 are created among adjacent blind holes 702 and have a thickness of about 11 um. Although the walls 706 themselves may have a relative small dimension, a plurality of mesas 704 are formed in the space surrounded by four (4) adjacent blind holes 702 and have a much larger size than the walls 706. The mesas 704, without any surface treatment, may reflect impinging lights and reduce the emissivity of the susceptor. In an embodiment, the surface treatment of susceptor produces surface textures on the surfaces of the mesas 704 by forming a layer of nano/micro-structures on the surface of the mesas 704. The surface textures can be formed by a laser drilling process with less powerful lasers as described in the previous sections of the present application, or by some other laser ablation processes such as dual laser interference patterning.

FIG. 7b illustrates a surface texture 708 formed on a surface of the susceptor, according to an embodiment of the present disclosure. The susceptor is made of silicon carbide. The surface texture 708 is shown to have a roughened appearance, which includes nano/micro-structures created by a less powerful laser pulse than that of forming blind holes. FIG. 7b also shows scribed lines 710 and 712 formed by overlapped blind holes. In an embodiment, the average size of structures of the surface texture 708 is less than 2 um, 1 um, or 0.5 um depending on the process parameters and materials of the susceptor. In an embodiment, the thickness of the surface texture is less than 5 um or 2 um.

To form the blind holes and surface textures, a susceptor is processed by the process tool 300 according to predetermined process parameters. The process parameters of the process tool are selected to satisfy a plurality of requirements, including forming blind holes of sufficient depth, controlling the thermal effect introduced by the processes to keep dimensional stability of the susceptor, producing a high-speed throughput, and/or keeping the high thermal strength of the susceptor during service.

### Process Parameters for a Graphite Susceptor

In an embodiment, a laser drilling process is implemented to create the blind holes in a graphite susceptor. The graphite susceptor may include a body made of graphite and one or more silicon carbide layers deposited on the surface. The laser used in the laser drilling process may be a diode pumped solid state laser with a near infrared wavelength in the range of 1 um to 1.5 um. The laser has a pulse width in the range of 15 ns to 30 usec or in the range of 0.5 usec to 10 usec. The laser pulse energy ranges from 0.1 mJ to over 100 mJ or in the range of 0.5 to 5 mJ. The pulse frequency may be in the range of 1 kHz to 1 MHz or in the range of 5 to 100 KHz. The average power of the laser may be in the range of 30 W to 200 W or higher.

The laser drilling process applies a limited number of pulses to form one blind hole. In one example, the laser drilling process applies one pulse to form one blind hole. The laser drilling parameters include controlling a focal spot diameter of the laser to be in the range of 5 um to 30 um or in the range of 10 to 20 um. The pulse energy is selected to be in the range of 0.2 mJ to 10 mJ or 0.5 mJ to 3 mJ. The pulse width is selected to be in the range of 0.2 usec to 20 usec or in the range 0.5 usec to 5 usec. The laser pulse frequency is selected to be in the range of 1 kHz to 1 MHz or in the range of 10 KHz to 100 KHz.

In one example, a galvanometer may be used as the scanner with a scanning speed range of 1 m/sec to 10 m/sec or in the range of 2 to 5 m/sec. In another example, a polygon scanner may be used with a scanning speed of 10 to 400 m/sec. The scanning speed may be adjusted based on the hole-to-hole spacing requirement and the pulse frequency. The laser beam can be a single beam or be split into an array of laser beams by using beam splitting devices, such as diffractive optical element (DOE). The use of an array of split beam to drilling multiple holes in parallel can further improve drilling throughput.

In an example, the following process parameters have formed blind holes and achieved 0.96 or higher emissivity or higher at 1 um wavelength for a graphite susceptor.

(a). Laser focal spot size=20 um, pulse rate=25 kHz, pulse width=10 usec, average power=50 W, pulse energy=2 mJ, 1 hole per pulse, scanning speed=5 m/sec; (b). Laser focal spot size=20 um, pulse rate=10 kHz, pulse width=10 usec, average power=40W, pulse energy=4 mJ, 1 hole per pulse, scanning speed=2 m/sec; or (c). Laser focal spot size=20 um, pulse rate=25 kHz, pulse width=5 usec, average power=50 W, pulse energy=2mJ, 1 hole per pulse, scanning speed=5 m/sec.

In an embodiment, the surface texturing process is implemented after the laser drilling process. The surface texturing process may use the same laser but with a large spot size and less energy.

### Process Parameters for a Silicon Carbide Susceptor or a Tantalum Carbide Susceptor

In an embodiment, a laser drilling process is implemented to create the blind holes in a silicon carbide susceptor or a tantalum carbide susceptor. The laser is a diode pumped solid state laser, such as a near infrared wavelength in the range of 1 um to 1.5 um or a green laser wavelength with wavelength in the range of 500 nm to 700 nm. The laser has a pulse width in the range of 50 femtoseconds to 10 picoseconds or in the range of 150 femtoseconds to 1 picosecond. The maximum laser pulse energy ranges from 0.1 mJ to 5 mJ or in the range of 0.5 mJ to 1 mJ. A corresponding pulse frequency is in the range of 1 kHz to 5 GHz or in the range of 0.5 GHz to 1 GHz. The laser average power is in the range of 30 W to 200 W. The laser can output pulse trains at a fixed pulse frequency from 0.1 kHz to 100 MHz or from 100 kHz to 10 MHz. The laser can also output bursts of pulses to further optimize hole geometry. The frequency of bursts is adjustable in the range of 1 KHz to 100 MHz or in the range of 100 KHz to 10 MHz. The number of pulses in a burst is in the range of 2 to 500 or in the range of 100 to 500.

In an embodiment, the laser drilling process for a silicon carbide susceptor or a tantalum carbide susceptor applies single or multiple bursts of pulses to form a blind hole. The drilling parameters include applying the above IR or Green laser with a focal spot diameter in the range of 5 um to 30 um or in the range of 10 to 20 um, pulse energy in the range of 0.05 mJ to 10 mJ or 0.1 mJ to 3 mJ, the pulse width in the range of 50 femtoseconds to 10 picoseconds or in the range of 150 femtoseconds to 1 picosecond, and laser pulse frequency in the range of 1 kHz to 5 GHz or the range of 1 GHz or above. The number of pulses in a burst is in the range of 2 to 500 or in the range of 100 to 300. The number of bursts is in the range of 1 to 30 or in the range of 2 to 10. Using the bursts of pulses can increase drilling throughput.

In one example, a galvanometer may be used as the scanner with a scanning speed range of 1 m/sec to 10 m/sec or in the range of 2 to 5 m/sec. In another example, a polygon scanner may be used with a scanning speed of 10 to 400 m/sec. The scanning speed may be adjusted based on the hole-to-hole spacing requirement and the pulse frequency. The laser beam can be a single beam or be split into an array of laser beams by using beam splitting devices, such as diffractive optical element (DOE). The use of an array of split beam to drilling multiple holes in parallel can further improve drilling throughput.

The laser drilling process applied to a silicon carbide susceptor or a tantalum carbide susceptor causes the physical removal of materials by vaporizing and ejecting melted SiC or TaC. The ejected materials may be redeposited on the susceptor and form debris. In an embodiment, a water soluble layer, such as polyvinyl-alcohol (PVA), is coated on the surface of the SiC susceptor or the TaC susceptor prior to the laser drilling process, so that the redeposited debris can be removed by water after the laser drilling process. In another embodiment, the laser drilling process may be implemented in an inertial gas environment, such argon gas, to avoid oxidization of Si to form SiO2. A wet chemical process may be implemented to remove Si.

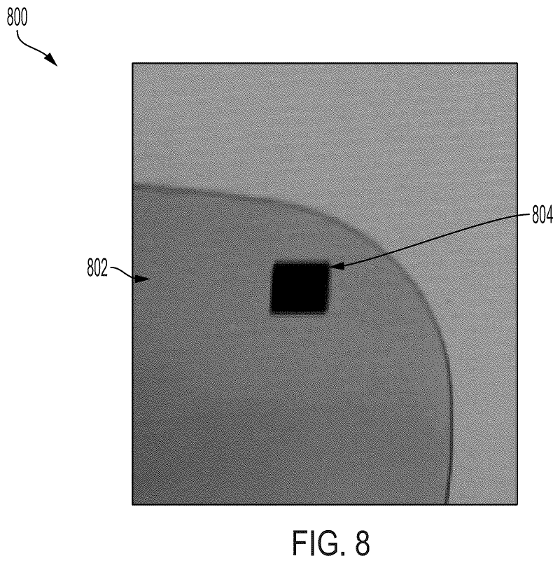

FIG. 8 illustrates a silicon carbide substrate 800 with a treated surface, according to an embodiment of the present disclosure. The silicon carbide substrate 800 may be formed by any suitable process, such as CVD, sublimation, the Atchison process, and liquid phase growth. The untreated part 802 of the silicon carbide substrate 800 is transparent. The silicon carbide substrate 800 includes a treated part 804 according to embodiment of the present disclosure. The treated part 804 show a dark color, which suggests a high emissivity that almost has no light reflected or emitted. The emissivity of the treated part 806 is about 0.96.

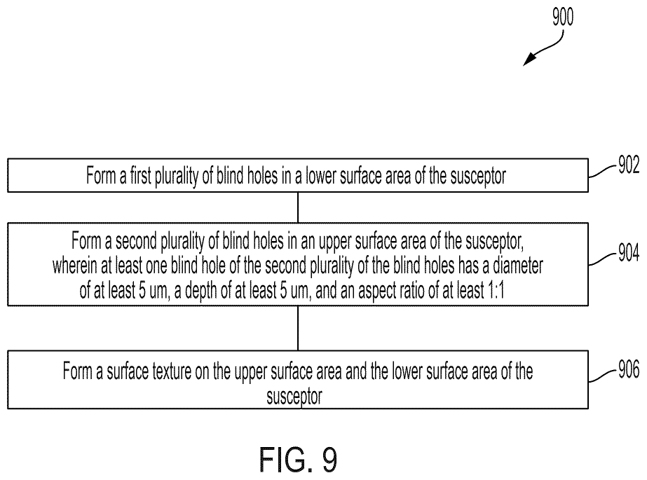

FIG. 9 illustrates a method 900 for improving an emissivity of a susceptor. At operation 902, the method forms a first plurality of blind holes in a lower surface area of the susceptor. A laser drilling apparatus may be used to form the first plurality of blind holes. At operation 904, the method forms a second plurality of blind holes in an upper surface area of the susceptor. A similar laser drilling apparatus may be used to form the second plurality of blind holes. The parameters of the laser drilling apparatus are configured to form at least one blind hole of the second plurality of the blind holes that has a diameter of at least 5 um, a depth of at least 5 um, and an aspect ratio of at least 1 um. At operation 906, the method forms a surface texture on the upper surface area and the lower surface area of the susceptor. A similar laser drilling apparatus may be used to form the surface texture. Process parameters are configured to cause the laser drilling apparatus to produce a less powerful laser. For example, the laser may have a larger spot diameter, a shorter pulse width, and/or a smaller pulse energy.

It is contemplated that one or more aspects disclosed herein may be combined. Moreover, it is contemplated that one or more aspects disclosed herein may include some or all of the aforementioned benefits. While the foregoing is directed to embodiments of the present disclosure, other and further embodiments of the disclosure may be devised without departing from the basic scope thereof, and the scope thereof is determined by the claims that follow.

What is claimed is:

1. A susceptor for supporting a substrate inside a processing chamber, the susceptor comprising:
a body having an upper surface area and a lower surface area;
a first plurality of blind holes formed in the upper surface area of the body; and
a second plurality of blind holes formed in the lower surface area of the body, wherein at least one blind hole from the first and second plurality of blind holes has a diameter of at least 5 um, a depth of at least 5 um, and an aspect ratio of at least 1:1.

2. The susceptor of claim 1, further comprising:
walls separating adjacent blind holes in the first plurality of blind holes and having a thickness no greater than 15 um.

3. The susceptor of claim 2, wherein the first plurality of blind holes include at least two adjacent rows of blind holes, and blind holes in the two adjacent rows are offset from each other such that a blind hole in one of the two adjacent rows is disposed between two blind holes in the other one of the two adjacent rows.

4. The susceptor of claim 1, further comprising:
a layer of protective material disposed on the upper surface area of the body; and
a layer of protective material disposed on the lower surface area of the body.

5. The susceptor of claim 4, wherein the layer of protective material disposed on the upper surface area of the body has an emissivity value greater than that of the body.

6. The susceptor of claim 4, wherein the layer of protective material disposed on the upper surface area of the body includes silicon carbide.

7. The susceptor of claim 4, wherein the first plurality of the blind holes extend through the layer of protective material disposed on the upper surface area of the body.

8. The susceptor of claim 1, further comprising a surface texture formed on the upper surface area of the body.

9. The susceptor of claim 8, wherein the surface texture is formed on a mesa on the upper surface area among the first plurality of the blind holes.

10. The susceptor of claim 8, wherein an emissivity value of the susceptor is higher than 0.95 for a light having a wavelength of about 1 um.

11. The susceptor of claim 1, wherein the body is made of graphite.

12. The susceptor of claim 11, wherein the first plurality of blind holes are formed by a laser drilling process.

13. The susceptor of claim 1, wherein the body is made of silicon carbide or tantalum carbide.

14. The susceptor of claim 1, wherein the first plurality of blind holes overlap with each other and form a scribed line.

15. A method for improving emissivity of a susceptor, the method comprising:
forming a first plurality of blind holes in a lower surface area of the susceptor;
forming a second plurality of blind holes in an upper surface area of the susceptor, wherein at least one blind hole of the second plurality of the blind holes has a diameter of at least 5 um, a depth of at least 5 um, and an aspect ratio of at least 1:1; and
forming a surface texture on the upper surface area and the lower surface area of the susceptor.

16. The method of claim 15, wherein the susceptor includes a body made of graphite, and forming the second plurality of the blind holes further comprises:
drilling the upper surface area with a pulsed laser to form the second plurality of the blind holes, the pulsed laser forming a single blind hole with a single laser pulse and having:
a focal spot diameter in a range of 5 um to 30 um;
a pulse energy in a range of 0.2 mJ to 10 mJ;
a pulse width in a range of 0.2 usec to 20 usec; and
a pulse frequency in a range of 1 kHz to 1 MHz.

17. The method of claim 15, wherein the susceptor includes a body made of silicon carbide or tantalum carbide, and forming the second plurality of blind holes further comprises:
drilling the upper surface area with a pulsed laser to form the second plurality of the blind holes, the pulsed laser forming a single blind hole with a burst of more than one laser pulses and having:
a focal spot diameter in a range of 5 um to 30 um;
a pulse energy in a range of 0.05 mJ to 10 mJ;
a pulse width in a range of 50 femtoseconds to 10 picoseconds; and
a pulse frequency in a range of 1 kHz to 5 GHz.

18. The method of claim 17, further comprising:
coating the upper surface area of the susceptor with a layer of a water-soluble material.

19. The method of claim 15, wherein forming the surface texture includes roughening a mesa formed in a space located among adjacent blind holes of the second plurality of blind holes.

20. A processing chamber for processing a substrate, the processing chamber comprising:
a susceptor comprising a body, the body having an upper surface area and a lower surface area; and
a heating lamp operable to heat the susceptor,
wherein a plurality of blind holes are formed in the upper surface area and the lower surface area, at least one blind hole of the plurality of the blind holes has a diameter of at least 5 um, a depth of at least 5 um, and an aspect ratio of at least 1:1.
